(19) United States
(12) Patent Application Publication
(10) Pub. No.: US 2026/0255772 A1
(43) Pub. Date: Aug. 27, 2026

(54) COMPOSITIONS, DIELECTRIC MATERIALS, ELECTRONIC DEVICES, AND METHODS OF FORMING THE SAME

(71) Applicant: CORNING INCORPORATED, CORNING, NY (US)

(72) Inventors: Mingqian He, Horseheads, NY (US); Xin Li, Shanghai (CN); Yang Li, Painted Post, NY (US)

(21) Appl. No.: 18/994,356

(22) PCT Filed: Jul. 12, 2023
(86) PCT No.: PCT/US23/27436

§ 371 Date: Jan. 14, 2025

(30) Foreign Application Priority Data
Jul. 18, 2022 (CN) 202210841661.1

(51) Int. Cl. H10K 10/46; G03F 7/075; G03F 7/16; H01G 4/14; H10K 71/40

(52) U.S. Cl. CPC H10K 10/471; G03F 7/0755; G03F 7/168; H01G 4/14; H10K 71/40

(57) ABSTRACT

A dielectric material is a thermoset polymer that is a copolymer of a first monomer and a second monomer. The first monomer can comprise a dipolar functional group having a dipole monomer of about 3.9 Debye or more. The first monomer can comprise a sulfur atom. The second monomer is a functionalized oligomeric silsesquioxane. The thermoset polymer can have a dielectric constant from about 15 to about 35 at 1000 Hertz. Methods can include disposing a precursor solution on a substrate. Methods can include heating the precursor solution to form a precursor layer. Methods can include disposing a photomask on a covered portion of the precursor layer and irradiating an exposed portion of the precursor layer to form the dielectric material. Methods can include removing the photomask and contacting the covered portion with a developing solution.

### CROSS-REFERENCE TO RELATED APPLICATIONS

This application claims the benefit of priority of Chinese Patent Application Serial No. 202210841661.1, filed on Jul. 18, 2022, the content of which is relied upon and incorporated herein by reference in its entirety.

### FIELD

The present disclosure relates generally to compositions, dielectric materials, electronic devices, and methods of making the same and, more particularly, to compositions for forming a polymer, dielectric materials comprising a polymer, electronic devices comprising a polymer, and method of making the same.

### BACKGROUND

Electronic devices include semiconductors (e.g., thin-film transistors (TFTs)) and capacitors. Organic thin-film transistors (OTFTs) have garnered extensive attention as alternatives to conventional silicon-based technologies, which require high temperature and high vacuum deposition processes, as well as complex photolithographic patterning methods. Semiconducting (e.g., organic semiconducting (OSC)) layers are one important component of OTFTs, which can effectively influence the performance of devices.

Traditional technologies in the manufacture of inorganic TFT device arrays often rely on photolithography as the patterning process involving harsh oxygen plasma during pattern transfer or photoresist removal and aggressive developing solvents which may severely damage the OSC layer and lead to significant deterioration of device performance.

Also, the performance of TFTs or OTFTs can be improved with a dielectric layer. There is a need to develop high dielectric constant (e.g., about 15 or more at 1000 Hertz (Hz)) organic materials that can be used in OTFTs or other electronic devices. Further, there is a need for organic dielectric materials that can be patterned using photolithography and where uncured material can be removed without the use of plasma or aggressive developing solvents.

### SUMMARY

There are set forth herein compositions for forming a polymer, dielectric materials comprising a polymer, and electronic devices containing the dielectric materials comprising a polymer. The dielectric material comprises a thermoset polymer, which reduces concerns about dimensional stability at elevated temperatures relative to a thermoplastic polymer. The dielectric material provides an organic polymer comprising a high dielectric constant (e.g., about 15 or more) that can improve the performance of electronic devices (e.g., OTFTs, capacitors) that it is incorporated in. The dielectric material and/or the first monomer comprises a dipolar functional group can reduce a decrease in dielectric constant as frequency increases to provide a more uniform dielectric constant across frequencies and a relatively higher dielectric constant at higher frequencies than might otherwise be expected. The dielectric material can comprise a low surface roughness Ra (e.g., about 5 nanometers or less or about 1 nanometer or less).

The dielectric material can be formed as a random copolymer of a first monomer and a second monomer. Providing a functionalized oligomeric silsesquioxane can increase a degree of branching and/or cross-linking of the resulting dielectric material, which can increase an effectiveness of photopatterning the dielectric material and/or reduce processing time. Providing more of the second monomer than the first monomer can produce well-defined, photo-patterned structures, for example, because the functionalized oligomeric silsesquioxanes can increase a cross-linking density of the resulting dielectric material. Providing a ratio of the second monomer to the first monomer of about 3 or less can enable a high dielectric constant. Providing a first monomer containing a glycidyl functional group and/or an epoxy functional group as well as a second monomer containing a glycidyl functional group and/or an epoxy functional group can simplify the curing reaction while allowing for a random copolymer to form, become cross-linked, and/or become branched. The dielectric material can be photopatterned and developed with a common solvent, reducing processing complexity and cost.

Providing a cationic photoinitiator allows the epoxy- and/or glycidyl-containing monomers to cure to produce a photo-patternable dielectric material. Providing a photosensitizer can increase a state of cure and/or a curing rate for the composition, which can minimize processing time and/or improve the resolution of a resulting photo-patterned dielectric material. Heating the precursor solution (e.g., composition) before irradiating the precursor solution can remove solvent, which can increase a subsequent polymerization reaction rate to reduce an overall processing time. Heating the dielectric material after irradiating the precursor layer can increase a spatial resolution of the patterned dielectric material. Providing a composition substantially free and/or free of nanoparticles (e.g., silica nanoparticles) can reduce processing issues (e.g., agglomeration, aggregation, phase separation) with the composition, improve optical properties (e.g., maintain low haze and/or high transmittance even after aging at elevated temperature and/or humidity) of the coating and/or the resulting coating and/or coated article, and reduce mechanical properties (e.g., hardness, modulus, strain) of the resulting dielectric material compared to a corresponding composition and/or dielectric material comprising a plurality of functionalized oligomeric silsesquioxanes without silica nanoparticles.

Some example aspects of the disclosure are described below with the understanding that any of the features of the various aspects may be used alone or in combination with one another.

Aspect 1. A dielectric material comprising:
a thermoset polymer comprising a random copolymer of:
   a first monomer comprising a dipolar functional group and a first functional group, the dipolar functional group comprising a dipole moment of about 3.9 Debye or more; and
   a second monomer comprising a functionalized oligomeric silsesquioxane,
wherein the thermoset polymer comprises a dielectric constant ranging from about 15 to about 35 at 1000 Hertz.

Aspect 2. the dielectric material of aspect 1, wherein the dipolar functional group is selected from a group consisting of sulfones, sulfates, cyanides, and thiiranes.

Aspect 3. A dielectric material comprising:
a thermoset polymer comprising a copolymer of:
   a first monomer comprising a sulfur atom and a first functional group, the first functional group comprising a glycidyl functional group or an epoxy functional group; and
   a second monomer comprising a functionalized oligomeric silsesquioxane functionalized by a glycidyl functional group or an epoxy functional group.

Aspect 4. The dielectric material of aspect 3, wherein the thermoset polymer comprises a dielectric constant ranging from about 15 to about 35 at 1000 Hertz.

Aspect 5. The dielectric material of any one of aspects 1-4, wherein the first monomer and the second monomer are bonded together by an alcohol or an ether.

Aspect 6. The dielectric material of any one of aspects 1-5, wherein the functionalized oligomeric silsesquioxane is a functionalized polyhedral oligomeric silsesquioxane.

Aspect 7. The dielectric material of any one of aspects 1-6, wherein a ratio in wt % of the second monomer to the first monomer ranges from about 1 to about 3.

Aspect 8. The dielectric material of any one of aspects 1-7, wherein a major surface of the dielectric material comprising a surface roughness Ra of about 5 nanometers or less.

Aspect 9. The dielectric material of any one of aspects 1-8, further comprising a photoinitiator comprising from about 1 wt % to about 5 wt % of the dielectric material.

Aspect 10. A transistor comprising the dielectric material of any one of aspects 1-9.

Aspect 11. A capacitor comprising the dielectric material of any one of aspects 1-9.

Aspect 12. An electronic device comprising the dielectric material of any one of aspects 1-11.

Aspect 13. A method of forming a dielectric material comprising:
disposing a precursor solution on a substrate;
heating the precursor solution at a first temperature from about 80° C. to about 150° C. for a first period of time from about 1 minute to about 5 minutes to form a precursor layer;
irradiating a portion of the precursor layer to form the dielectric material; and
contacting the covered portion with a developing solution to remove the covered portion of the precursor layer,
wherein the dielectric material is a thermoset polymer.

Aspect 14. The method of aspect 13, further comprising, before the irradiating, disposing a photomask on a covered portion of the precursor layer.

Aspect 15. The method of aspect 13, further comprising, before contacting the covered portion with the developing solution, heating the dielectric material at a second temperature from about 90° C. to about 150° C. for a second period of time from about 2 minutes to about 20 minutes.

Aspect 16. The method of any one of aspects 13-15, wherein irradiating the exposed portion comprising delivering a dose from about 100 milliJoules per centimeters squared (mJ/cm²) to about 1,600 mJ/cm².

Aspect 17. The method of any one of aspects 13-16, wherein the precursor solution comprises:
a solvent;
a first monomer comprising a first functional group and either a dipolar functional group comprising a dipole moment of about 3.9 Debye or more or a sulfur atom;
a second monomer comprising a functionalized oligomeric silsesquioxane; and
a photoinitiator.

Aspect 18. The method of aspect 17, wherein the first monomer comprises the dipolar functional group, the dipolar functional group is selected from a group consisting of sulfones, sulfates, cyanides, and thiiranes.

Aspect 19. The method of any one of aspects 17-18, wherein the first functional group is an epoxy functional group or a glycidyl functional group.

Aspect 20. The method of any one of aspects 17-19, wherein the functionalized oligomeric silsesquioxane is functionalized by a glycidyl functional group or an epoxy functional group.

Aspect 21. The method of any one of claims 17-20, wherein the functionalized oligomeric silsesquioxane is a functionalized polyhedral oligomeric silsesquioxane.

Aspect 22. The method of any one of aspects 17-21, wherein a ratio in wt % of the second monomer to the first monomer ranges from about 1 to about 3.

Aspect 23. The method of any one of aspects 13-22, wherein the thermoset polymer comprising a dielectric constant ranging from about 15 to about 35 at 1000 Hertz.

Aspect 24. A method of forming a compound comprising:
reacting cyclohex-3-enecarboxylic acid and 2-(methylthio)ethanol in a stoichiometric ratio to form an intermediate product; and
reacting the intermediate product in the presence of 3-chloroperoxybenzoic acid to form the compound.

Aspect 25. The method of aspect 23, wherein the compound is 3,4-gylcidylcycholhexylethoanatemethanesulfone.

Aspect 26. The method of any one of aspects 23-24, wherein the reacting cyclohex-3-enecarboxylic acid and 2-(methylthio)ethanol occurs at a temperature from about 20° C. to about 30° C. for a period of time from about 4 hours to about 16 hours.

Aspect 27. The method of any one of aspects 23-25, wherein a molar ratio of the intermediate product to the 3-chloroperoxybenzoic acid is about 4.

Aspect 28. The method of any one of aspects 23-26, wherein the reacting the intermediate product in the presence of 3-chloroperoxybenzoic acid occurs at a temperature from about 35° C. to about 50° C. for a period of time from about 36 hours to about 72 hours.

Aspect 29. The method of any one of aspects 23-27, wherein one or both reactions occur in the presence of dichloromethane as a solvent.

Aspect 30. A composition comprising:
a solvent;
a first monomer comprising a first functional group and either a dipolar functional group comprising a dipole moment of about 3.9 Debye or more or a sulfur atom;
a second monomer comprising a functionalized oligomeric silsesquioxane; and
a photoinitiator.

Aspect 31. The composition of aspect 30, wherein the first monomer comprises the dipolar functional group, the dipolar functional group is selected from a group consisting of sulfones, sulfates, cyanides, and thiiranes.

Aspect 32. The composition of any one of aspects 30-31, wherein the first functional group is an epoxy functional group or a glycidyl functional group.

Aspect 33. The composition of any one of aspects 30-32, wherein the functionalized oligomeric silsesquioxane is functionalized by a glycidyl functional group or an epoxy functional group.

Aspect 34. The composition of any one of claims 30-33, wherein the functionalized oligomeric silsesquioxane is a functionalized polyhedral oligomeric silsesquioxane.

Aspect 35. The composition of any one of aspects 30-34, wherein a ratio in wt % of the second monomer to the first monomer ranges from about 1 to about 3.

Aspect 36. The composition of any one of aspects 30-35, wherein the photoinitiator is present in an amount from about 1 wt % to about 5 wt % of the composition.

Aspect 37. The composition of any one of aspects 30-36, further comprising a photosensitizer in an amount from about 0.1 wt % to about 5 wt % of the composition.

Aspect 38. The composition of any one of aspects 30-37, wherein the solvent is present in an amount from about 0.1 wt % to about 2 wt % of the composition.

### BRIEF DESCRIPTION OF THE DRAWINGS

The above and other features and advantages of aspects of the present disclosure are better understood when the following detailed description is read with reference to the accompanying drawings, in which:

FIG. 1 is a schematic view of an example electronic device comprising a thin-film transistor (TFT) according to aspects of the disclosure;

FIG. 2 is a schematic view of an example electronic device comprising a capacitor according to aspects of the disclosure;

FIGS. 3-6 schematically show reactions to form a material of a dielectric material in accordance with aspects of the disclosure;

FIG. 7 schematically shows a reaction to form an epoxy-functionalized sulfonate in accordance with aspects of the disclosure;

FIG. 8 is a flow chart illustrating example methods of making coatings and/or coated articles in accordance with the aspects of the disclosure;

FIG. 9 schematically illustrates an exemplary step in methods of making an electronic device comprising heating a precursor liquid disposed on a substrate;

FIG. 10 schematically illustrates an exemplary step in methods of making an electronic device comprising irradiating at least a portion of the precursor liquid; and

FIG. 11 schematically illustrates an exemplary step in methods of making an electronic device comprising removing uncured precursor liquid.

Throughout the disclosure, the drawings are used to emphasize certain aspects. As such, it should not be assumed that the relative size of different regions, portions, and substrates shown in the drawings are proportional to its actual relative size, unless explicitly indicated otherwise.

### DETAILED DESCRIPTION

Aspects will now be described more fully hereinafter with reference to the accompanying drawings in which example aspects are shown. Whenever possible, the same reference numerals are used throughout the drawings to refer to the same or like parts.

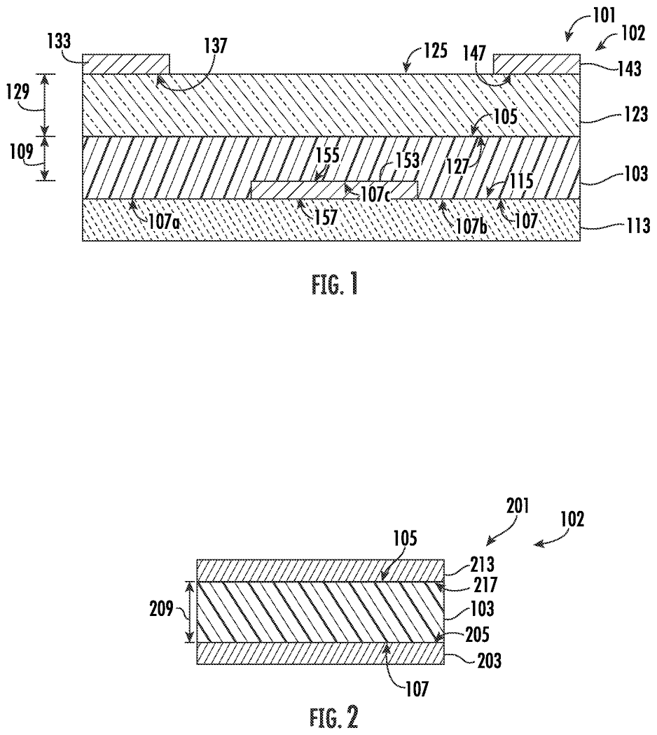

The dielectric material of aspects of the disclosure can be used in an electronic device 102 illustrated in FIGS. 1-2. The electronic device 102 can comprise, for example, a transistor 101 (e.g., thin-film transistor (TFT), organic TFT (OTFT)) or a capacitor 202 as illustrated in FIGS. 1-2, respectively. The dielectric material can be formed by curing a composition. However, it is to be understood that the dielectric material is not limited to such applications and can be used in other applications. Unless otherwise noted, a discussion of features of aspects of one composition, dielectric material, or electronic device can apply equally to corresponding features of any aspect of the disclosure. For example, identical part numbers throughout the disclosure can indicate that, in some aspects, the identified features are identical to one another and that the discussion of the identified feature of one aspect, unless otherwise noted, can apply equally to the identified feature of any other aspect of the disclosure.

Aspects of the disclosure can comprise dielectric materials. The dielectric materials comprise thermoset polymers. As used herein, thermoset polymers cannot be reformed after an initial curing reaction. A thermoset polymer is to be contrasted with a thermoplastic polymer, which softens when heated such that the thermoplastic material can be reformed after an initial polymerization reaction. In contrast, thermoset materials. The thermoset polymer can be a random copolymer of a first monomer comprising a dipolar functional group and a second monomer comprising a functionalized oligomeric silsesquioxane. As used herein, a random copolymer does not require a certain orientation between adjacent monomers in the thermoset polymer. For example, a first monomer can be adjacent to two first monomers, one first monomer and one second monomer, or two second monomers. A random copolymer is to be contrasted with an alternating copolymer, where every first monomer is only adjacent to two second monomers, or a block copolymer, where all of the first monomers are clumped together in one or more blocks.

In aspects, the first monomer comprises a dipolar functional group and a first functional group. As used herein, a “dipolar functional group” comprises a dipole moment of about 3.9 or more. In further aspects, the dipolar functional group can comprise a quinoline, a pyrrole, a pyridine, a nitrobenzene, a benzamide, an amide, a cyanide, a sulfone, a sulfate, a thiirane, or combinations thereof. Exemplary aspects of the dipolar functional group include sulfones, sulfates, cyanides, thiiranes, and combinations thereof. A sulfone comprises a sulfonyl functional group attached to two carbon atoms. An exemplary aspect of a sulfone is a methyl sulfone with the other carbon atom attaching the sulfone to the first functional group, although other alkyl sulfones are possible. A sulfate comprises a sulfur atom surrounded by four oxygen atoms, and one or more of these oxygen atoms can be attached to a carbon atom attaching the sulfate to the first functional group. In aspects, the first monomer comprises a sulfur atom and the first functional group. In further aspects, the sulfur atom can be part of a sulfone, a sulfate, or a thiirane. In even further aspects, the sulfur atom can be part of a sulfone, for example, a methyl sulfone. Providing a dipolar functional group in the first monomer used to form the dielectric material can reduce a decrease in dielectric constant as frequency increases to provide a more uniform dielectric constant across frequencies and a relatively higher dielectric constant at higher frequencies than might otherwise be expected.

In aspects, the first functional group of the first monomer can comprise an epoxy functional group and/or a glycidyl functional group. Exemplary aspects of epoxies include epoxy, alkyl epoxy (e.g., epoxyethyl, epoxypropyl), and cycloalkyl epoxy (e.g., epoxycyclohexyl). Exemplary aspects of glycidyl functional groups include amine glycidyls, alkyl glycidyls (e.g., glycidylpropyl), ether glycidyls (e.g., glycidyloxy), siloxane glycidyls (e.g., glycidyldimethyoxy), and combinations thereof (e.g., glycidyloxypropyl, glycidyloxypropyldimethylsiloxy).

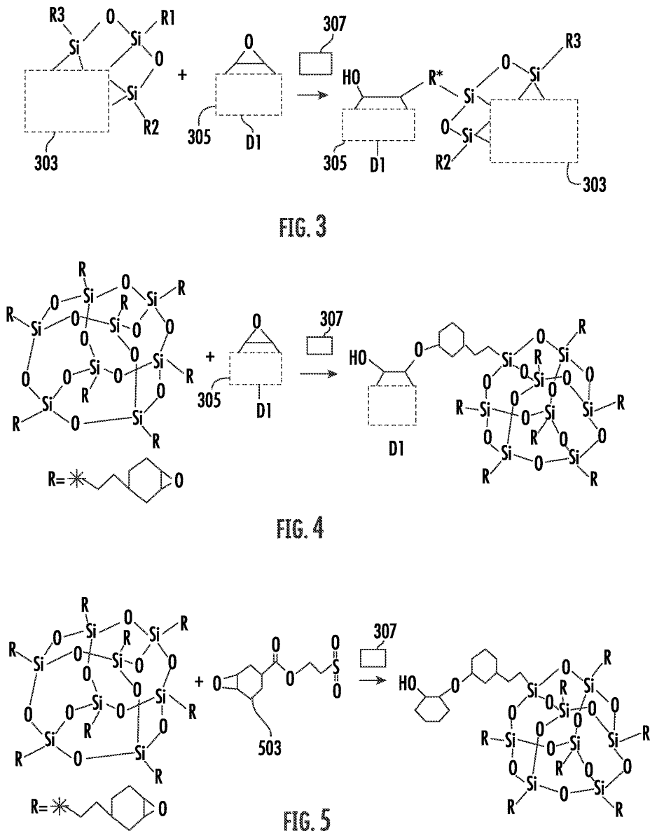

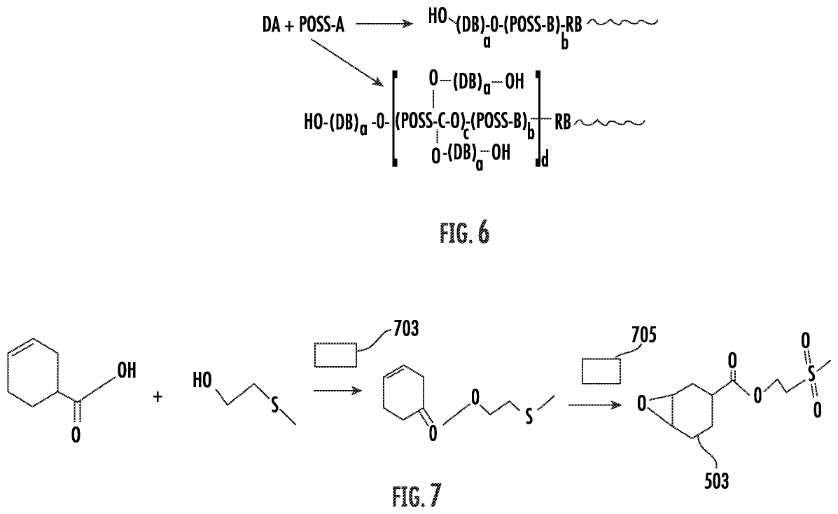

As shown FIGS. 5 and 7, an exemplary aspect of the first monomer 503 comprises a methyl sulfone (i.e., sulfur containing, dipolar functional group) attached to an epoxy cyclohexyl functional group (i.e., first functional group) by a carboxylic acid functional group. Throughout the disclosure, the first monomer 503 shown in FIGS. 5 and 7 is referred to as 3,4-gylcidylcycholhexylethoanatemethanesulfone. FIG. 7 shows a reaction process for obtaining the first monomer 503. Cyclohex-3-enecarboxylic acid is reacted with 2-(methylthio)ethanol in a stoichiometric ratio (i.e., 1:1 molar ratio) under the reaction conditions in box 703, which is in dichloromethane at 25° C. overnight. The product of this reaction is purified by filtration and chromatography, and then reacted with 3-chloroperoxybenzoic acid in a 4:1 molar ratio under the reaction conditions in box 705, which is in dichloromethane at 40° C. for two days. The product of this second reaction is the first monomer 503, which was obtained after purification by filtration and chromatography.

The second monomer comprises a functionalized oligomeric silsesquioxane. As used herein a functionalized oligomeric silsesquioxane means an organosilicon compound comprises at least two monomers represented as RSiO_{1.5}, where there are three oxygen atoms with each oxygen atom shared with another monomer bonded thereto and R is a functional group that “functionalizes” an oligomeric silsesquioxane to form the functionalized oligomeric silsesquioxane, although the R of one monomer need not be the same as the R of another monomer. In aspects, a number of the RSiO_{1.5} monomers in the functionalized oligomeric silsesquioxane can be a whole number of 4 or more, 6 or more, 8 or more, 50 or less, 30 or less, 20 or less, 16 or less, about 12 or less, or 10 or less. In aspects, a number of the RSiO_{1.5} monomers in the functionalized oligomeric silsesquioxane can be a whole number in a range from 4 to 50, 4 to 30, 4 to 20, 6 to 20, 6 to 16, 6 to 12, 8 to 12, 8 to 10, or any range or subrange therebetween. For example, the far left compound of FIGS. 3-5 show examples of functionalized oligomeric silsesquioxanes.

In aspects, the functionalized oligomeric silsesquioxane can further comprise any number of RSiO₂ monomers in addition to the RSiO_{1.5} monomeric units discussed above, where again the R can vary between monomers of either or both the RSiO₂ monomers and RSiO_{1.5} monomers. In further aspects, a RSiO₂ monomer can be a terminal monomer, meaning that it is connected to only one other monomer. For simplicity, these “terminal monomers” will be referred to as RSiO₂ with the understanding that terminal RSiO₂ monomers can refer to either RSiO_{3.5}, RSiO_{2.5}, R₂SiO_{3.5}, R₂SiO_{2.5}, R₂SiO_{1.5}, R₃SiO_{3.5}, R₃SiO_{2.5}, R₃SiO_{1.5}, or R₃SiO_{0.5}, where a first R of a single terminal monomer can be the same as or different from another (e.g., one, all) R of the same single terminal monomer. In further aspects, a RSiO₂ monomer can be bonded to two other monomers. For example, a RSiO₂ monomer can be bonded to another RSiO₂ and a RSiO_{1.5} monomer or two RSiO_{1.5} monomers. For simplicity, “non-terminal RSiO₂ monomers” can refer to either RSiO₃, RSiO₂, R₂SiO₃, or R₂SiO₂, where a first R of a single “non-terminal RSiO₂” monomer can be the same as or different from another (e.g., one, all) R of the same single “non-terminal RSiO₂ monomer.” In further aspects, the number of RSiO₂ monomers can be less than or equal to the number of RSiO_{1.5} monomers. For example, when the number of RSiO₂ monomers is 4 and the number of the RSiO_{1.5} monomers is 4 or more, a ladder-type functionalized oligomeric silsesquioxane can be formed, where each of the RSiO_{1.5} monomers is connected to two other RSiO_{1.5} monomers and either a RSiO_{1.5} monomer or a RSiO₂ monomer. In even further aspects, the far left compound of FIG. 3 can comprise a ladder-type functionalized oligomeric silsesquioxanes, for example, when box 303 makes the Si atom bonded to the R group and the Si atom bonded to the R2 group non-terminal RSiO₂ monomers, the R3 group an RSiO_{1.5} monomer, and the box 303 comprises three or more additional RSiO_{1.5} monomers and two more RSiO₂ monomers, which can be terminal or non-terminal.

In further aspects, the functionalized oligomeric silsesquioxane can comprise from 1 to 3 of RSiO₂ monomers (e.g., 1, 2, 3). In even further aspects, an adjacent pair of RSiO_{1.5} monomers can be connected to each other by two or more non-overlapping paths, where each path comprises at least one monomer other than the adjacent pair of RSiO_{1.5} monomers and the first path is connected to the second path without passing through the adjacent pair of monomers. For example, an open-cage functionalized oligomer silsesquioxane can comprise the adjacent pair of RSiO_{1.5} monomers connected to each other by two or more non-overlapping paths and the first path is connected to the second path without passing through the adjacent pair of monomers while also comprising from 1 to 3 of RSiO₂ monomers. In even further aspects, the far left compound of FIG. 3 can comprise an open-cage functionalized oligomer silsesquioxane, for example, when box 303 makes one or more of the Si atoms shown into an RSiO_{1.5} monomer such that a total number of RSiO₂ monomers is from 1 to 3, an adjacent pair of RSiO_{1.5} monomers is connected to each other by two or more non-overlapping paths, and the first path is connected to the second path without passing through the adjacent pair of monomers.

In aspects, the functionalized oligomeric silsesquioxane can consist of RSiO_{1.5} monomers. As used herein, a polyhedral oligomeric silsesquioxane (POSS) refers to a functionalized oligomer silsesquioxane consisting of RSiO_{1.5} monomers. Exemplary aspects of functionalized POSS can comprise 6, 8, 10, or 12 RSiO_{1.5} monomers, although other aspects are possible. For example, functionalized oligomeric silsesquioxane consisting of 8 RSiO_{1.5} monomers is an octahedral functionalized POSS (e.g., polyoctahedral silsesquioxane). As shown in FIGS. 4-5, the far left compound is a functionalized POSS, namely, an octahedral functionalized POSS.

In aspects, functionalized oligomeric silsesquioxanes can be formed from condensation reactions of silane. As used herein a condensation reaction produces an R₂O byproduct, where R can include any of the R units discussed below and can further comprise hydrogen (e.g., with a hydroxyl or water byproduct). For example, silanes (e.g., R₃OSi) can be reacted to form terminal RSiO₂ monomers. For example, a terminal RSiO₂ monomer can react with another RSiO₂ monomer (e.g., terminal, non-terminal) to form an RSiO_{1.5} monomer as an oxygen atom of one monomer forms a bond with a silicon atom of another monomer, producing the condensation byproduct. It is to be understood that the RSiO_{1.5} silsesquioxane monomers are different from siloxane monomers, which can include M-type siloxane monomers (e.g., R₃SiO_{0.5}), D-type siloxane monomers (e.g., R₂SiO₂), and/or silica-type siloxane monomers (SiO₂).

Functionalized oligomeric silsesquioxanes can be functionalized by one or more functional groups. As used herein, a functional group functionalizing the functionalized oligomeric silsesquioxane can exclude hydrogen, bisphenols, and/or fluorine-containing functional groups. In aspects, the functional group functionalizing the functionalized oligomeric silsesquioxane can exclude isocyanates, alkenes, and/or alkynes. In aspects, a functional group for the functionalized oligomeric silsesquioxane can comprise epoxies, a glycidyls, oxiranes, thiols, anhydrides, isocyanates, acrylates, and methacrylates. In further aspects, the functional group for the functionalized oligomeric silsesquioxane can be a glycidyl functional group or an epoxy functional group. Throughout the disclosure, a functionalized POSS that is functionalized by a glycidyl group is referred to as GPOSS. Exemplary aspects of glycidyl functional groups include amine glycidyls, alkyl glycidyls (e.g., glycidylpropyl), ether glycidyls (e.g., glycidyloxy), siloxane glycidyls (e.g., glycidyldimethyoxy), and combinations thereof (e.g., glycidyloxypropyl, glycidyloxypropyldimethylsiloxy). Commercially available examples of GPOSS include 3-glycidyloxypropyl functionalized POSS (e.g., EP0409 (Hybrid Plastics)), 3-glycidylpropoxy functionalized POSS (e.g., 560624 (Sigma Aldrich)), and 3-glycidyloxypropyldimethysiloxy (e.g., 593869 (Sigma Aldrich)). Exemplary aspects of epoxy functional groups include epoxy, alkyl epoxy (e.g., epoxyethyl, epoxypropyl), and cycloalkyl epoxy (e.g., epoxycyclohexyl). Commercially available examples of epoxy functionalized POSS include (3,4-epoxycyclohexyl)ethyl functionalized POSS (e.g., 560316 (Sigma Aldrich), EP0408 (Hybrid Plastics)). For example, the compound on the left in FIGS. 4-5 is an epoxy functionalized POSS, namely, (3,4-epoxycyclohexyl)ethyl functionalized POSS.

As shown in FIGS. 3-5, the locations where the functionalized oligomeric silsesquioxane can be functionalized are denoted as R-groups (e.g., R, R1, R2, R3). As used herein, the functionalized oligomeric silsesquioxane is functionalized by at least one of the functional groups listed in the previous paragraph. As shown in FIG. 3, the R-groups can be different from one another, although they can all be the same in other aspects. It is to be understood that the R-groups shown in FIGS. 4-5 can be different from one another or the same. In aspects, the functionalized oligomeric silsesquioxane (e.g., functionalized POSS) can comprise two or more R-groups comprising a functional group listed in the previous paragraph for functionalizing the oligomeric silsesquioxane. In further aspects, substantially every R-group of the functionalized oligomeric silsesquioxane can comprise a functional group listed in the previous paragraph for functionalizing the oligomeric silsesquioxane. In even further aspects, all of the R-groups comprising a functional group listed in the previous paragraph can comprise the same functional group. In further aspects, with reference to FIG. 3, the functionalized oligomeric silsesquioxane can be functionalized by a first functional group (R) selected from the list in the previous paragraph and a second functional group (R2) selected from the list in the previous paragraph, where R is different from R2. In further aspects, one or more of the R-groups can comprise a functional group other than those listed in the previous paragraph. For example, other potential R-groups include hydrogen, alkyls, cycloalkyls, alcohols, and amines. In even further aspects, with reference to FIG. 3, a third functional group (R3) of the functionalized oligomeric silsesquioxane can comprise hydrogen or an alkyl, cycloalkyl, alcohol, or amine functional group without comprising one of the functional groups listed in the previous paragraph.

Throughout the disclosure, an effective diameter of a molecule (e.g., functionalized oligomeric silsesquioxane) is measured using dynamic light scattering in accordance with ISO 22412:2017. In aspects, an effective diameter of a functionalized oligomeric silsesquioxane of the plurality of functionalized oligomeric silsesquioxanes can be about 20 nm or less, about 15 nm or less, about 10 nm or less, about 6 nm or less, about 1 nm or more, about 2 nm or more, or about 4 nm or more. In aspects, an effective diameter of a functionalized oligomeric silsesquioxane of the plurality of oligomeric silsesquioxanes can be in a range from about 1 nm to about 20 nm, from about 1 nm to about 15 nm, from about 2 nm to about 15 nm, from about 2 nm to about 10 nm, from about 4 nm to about 10 nm, from about 4 nm to about 6 nm, from about 1 nm to about 6 nm, from about 2 nm to about 6 nm, or any range or subrange therebetween. In further aspects, a mean effective diameter of the plurality of functionalized oligomeric silsesquioxanes can be within one or more of the ranges for the effective diameter of a functionalized oligomeric silsesquioxane discussed above. In further aspects, substantially all and/or all of the functionalized oligomeric silsesquioxanes of the plurality of functionalized oligomeric silsesquioxanes can be within one or more of the ranges for the effective diameter of a functionalized oligomeric silsesquioxane discussed above.

In aspects, a ratio of the second monomer to the first monomer, on a wt % basis, (e.g., in the composition or in the dielectric material) can be about 1 or more, about 1.5 or more, about 2 or more, about 3 or less, about 2.8 or less, or about 2.5. In aspects, the ratio of the second monomer to the first monomer, on a wt % basis, (e.g., in the composition or in the dielectric material) can range from about 1 to about 3, from about 1.5 to about 2.8, from about 2 to about 2.5, or any range or subrange therebetween. In aspects, a wt % of the first monomer to a total weight of the dielectric material and/or the composition can be about 20 wt % or more, about 25 wt % or more, about 30 wt % or more, about 35 wt % or more, about 50 wt % or less, about 45 wt % or less, about 40 wt % or less, about 35 wt %, or less, or about 30 wt % or less. In aspects, the wt % of the first monomer to the total weight of the dielectric material and/or the composition can range from about 20 wt % to about 50 wt %, from about 25 wt % to about 45 wt %, from about 30 wt % to about 40 wt %, from about 30 wt % to about 35 wt %, or any range or subrange therebetween. In aspects, a wt % of the second monomer to a total weight of the dielectric material and/or the composition can be about 45 wt % or more, about 50 wt % or more, about 55 wt % or more, about 60 wt % or more, about 65 wt % or more, about 75 wt % or less, about 70 wt % or less, about 65 wt % or less, or about 60 wt % or less. In aspects, the wt % of the second monomer to the total weight of the dielectric material and/or the composition can range from about 45 wt % to about 75 wt %, from about 50 wt % to about 70 wt %, from about 55 wt % to about 65 wt %, from about 60 wt % to about 65 wt %, or any range or subrange therebetween. Providing more of the second monomer than the first monomer can produce well-defined, photo-patterned structures, for example, because the functionalized oligomeric silsesquioxanes can increase a cross-linking density of the resulting dielectric material. Providing a ratio of the second monomer to the first monomer of about 3 or less can enable a high dielectric constant.

In aspects, the dielectric material and/or the composition can be substantially free from nanoparticles. In aspects, the dielectric material and/or the composition can be substantially free of silica nanoparticles. As used herein, the dielectric material and/or the composition is substantially free of silica nanoparticles if an amount of silica nanoparticles is about 1 wt % or less. In further aspects, the dielectric material and/or the composition can be free of silica nanoparticles. As used herein, silica nanoparticles refer to particles comprising an effective diameter of at least 20 nm and comprise silica. Silica nanoparticles can comprise solid particles or mesoporous particles. Silica nanoparticles can be larger (e.g., comprise a larger effective diameter) than a functionalized oligomeric silsesquioxane of the plurality of functionalized oligomeric silsesquioxanes. Silica nanoparticles can be formed from colloidal silica and/or via a sol-gel method. Without wishing to be bound by theory, silica nanoparticles can aggregate, especially at elevated temperature, impairing mechanical and/or optical properties of the composition or resulting dielectric material. Providing a composition substantially free and/or free of silica nanoparticles can reduce processing issues (e.g., agglomeration, aggregation, phase separation) with the composition, improve optical properties (e.g., maintain low haze and/or high transmittance even after aging at elevated temperature and/or humidity) of the coating and/or the resulting coating and/or coated article, and reduce mechanical properties (e.g., hardness, modulus, strain) of the resulting dielectric material compared to a corresponding composition and/or dielectric material comprising a plurality of functionalized oligomeric silsesquioxanes without silica nanoparticles.

In aspects, the composition and/or the dielectric material can comprise a catalyst. Without wishing to be bound by theory, a catalyst can increase a rate of the curing (e.g., polymerization, reaction), and the catalyst may avoid permanent chemical change as a result of the curing reaction. In aspects, the catalyst can comprise one or more platinum group metals, for example, ruthenium, rhodium, palladium, osmium, iridium, and/or platinum.

In aspects, the composition and/or the dielectric material can comprise a photoinitiator. As used herein a photoinitiator is a compound sensitive to one or more wavelengths that upon absorbing light comprising the one or more wavelengths undergoes a reaction to produce one or more radicals or ionic species that can initiate a reaction. In further aspects, the photoinitiator may be sensitive to one or more wavelengths of ultraviolet (UV) light. In further aspects, the photoinitiator can comprise a cationic photoinitiator, which is a photoinitiator configured to initiate a cation reaction (e.g., cationic polymerization). Example aspects of photoinitiators sensitive to UV light include without limitation benzoin ethers, benzil ketals, dialkoxyacetophenones, hydroxyalkylphenones, aminoalkylphenones, acylphosphine oxides, thioxanthones, hydroxyalkylketones, and thoxanthanamines. In further aspects, the photoinitiator may be sensitive to one or more wavelengths of visible light. Example aspects of photoinitiators sensitive to visible light include without limitation 5,7-diiodo-3-butoxy-6-fluorine, bis(4-methoxybenzoyl) dimethylgermanium, bis(2,4,6-trimethylbenzoyl)-phenylphosphineoxide, 3-methyl-4-aza-6-helicene, and thiocyanide borates. In further aspects, the photoinitiator may be sensitive to a wavelength that other components of the composition and/or the composition is substantially transparent at. In further aspects, the photoinitiator can initiate a cationic reaction (e.g., cationic polymerization), for example, triarylsulfonium hexafluoroantimonate, triphenylsulfonium hexafluoroantimonate, and bis(4-tert-butylphenyl)iodonium perfluoro-1-butanesulfonate. Commercially available photoinitiators include without limitation the Irgacure product line from BASF, for example tris(4-((4-acetylphenyl)thio)phenyl)-sulfonium tetrakis(perfluorophenyl)borate available as Irgacure PAG290 from BASF. In aspects, the composition and/or the dielectric material can comprise the photoinitiator in a weight % (wt %) of about 1 wt % or more, about 1.5 wt % or more, about 2 wt % or more, about 5 wt % or less, about 4 wt % or less, about 3 wt % or less, or about 2 wt % or less. In aspects, the composition and/or the dielectric material can comprise the photoinitiator ranging from about 1 wt % to about 5 wt %, from about 1.5 wt % to about 4 wt %, from about 2 wt % to about 3 wt %, or any range or subrange therebetween. In aspects, the composition and/or the dielectric material can be substantially free of fluorine-based compounds. As used herein, the composition and/or the dielectric material can be substantially free of fluorine-based compounds while containing a trace amount of fluorine in a minor component (e.g., about 6 wt % or less of a photoinitiator) of the corresponding to an overall wt % of fluorine of about 0.25 wt % or less. In further aspects, the composition and/or the dielectric material can be free of fluorine-based compounds.

In further aspects, the composition and/or the dielectric material can comprise a photosensitizer. As used herein, a photosensitizer is configured to absorb one or move wavelengths of light and transfer the corresponding energy to a nearby molecule (e.g., photoinitiator), for example, by donating an electron or abstracting a hydrogen atom. An exemplary aspect of a photosensitizer is 2-isopropylthioxanthen-9-one (available as Speedcure 2-ITX (Arkema or Sartomer), Photocure ITX-P (Eutec), etc.). In aspects, the composition and/or the dielectric material can comprise a wt % of the photosensitizer of about 0.1 wt % or more, about 0.5 wt % or more, about 1 wt % or more, about 2 wt % or more, about 5 wt % or less, about 4 wt % or less, or about 3 wt % or less. In aspects, the composition and/or the dielectric material can comprise the wt % of the photosensitizer ranging from about 0.1 wt % to about 5 wt %, from about 0.5 wt % to about 4 wt %, from about 1 wt % to about 3 wt %, from about 2 wt % to about 3 wt %, or any range or subrange therebetween. In aspects, the wt % of the photosensitizer can be the same or less than the wt % of the photoinitiator. Providing a photosensitizer can increase a state of cure and/or a curing rate for the composition, which can minimize processing time and/or improve the resolution of a resulting photo-patterned dielectric material.

In aspects, the composition can comprise a solvent. As used herein, “solvent” excludes the components discussed above, for example, functionalized oligomeric silsesquioxanes, linkers comprising a first functional group at the first end and a second functional group at the second end opposite the first end, silane coupling agents, catalysts, photoinitiators, and combinations and/or products thereof. Solvents can comprise one or more of a polar solvent (e.g., a non-protic polar solvent, an acetate, acetone, dimethylformamide, acetonitrile, dimethyl sulfoxone, nitromethane, ethylene carbonate, propylene carbonate, poly(ether ether ketone)) or a non-polar solvent (e.g., pentane, 1,4-dioxane, chloroform, dichloromethane, diethyl ether, hexane, heptane, benzene, toluene, xylene). Example aspects of alcohols include methanol, ethanol, propanol, butanol, cyclohexanol, hexanol, octanol, ethylene glycol, and propylene glycol. Example aspects of acetate include ethyl acetate, propyl acetate, and butyl acetate. In further aspects, the solvent can comprise butyl acetate, propyl acetate, and/or acetonitrile. Providing a solvent can enable the formation of coating using a wider range of compositions than would otherwise be possible. In aspects, the composition can comprise a wt % of the solvent of about 0.1 wt % or more, about 0.2 wt % or more, about 0.3 wt % or more, about 2 wt % or less, about 1 wt % or less, or about 0.5 wt % or less. In aspects, the composition can comprise the wt % of the solvent ranging from about 0.1 wt % to about 2 wt %, from about 0.2 wt % to about 1 wt %, from about 0.3 wt % to about 0.5 wt %, or any range or subrange therebetween.

In aspects, the composition can comprise a viscosity. As used herein, a viscosity of a liquid is measured at 23° C. using a rotational rheometer (e.g., RheolabQC from Anton Par or a Discovery Hybrid Rheometer (DHR-3) from TA Instruments) at a shear rates of about 0.83 1/second (s) (e.g., 50 revolutions per minutes (rpm)). In further aspects, the composition can comprise a viscosity of about 0.01 Pascal-seconds (Pa-s) or more, about 1 Pa-s or more, about 5 Pa-s or more, about 10 Pa-s or more, about 1,000 Pa-s or less, about 500 Pa-s or less, about 100 Pa-s or less, about 50 Pa-s or less, or about 30 Pa-s or less. In aspects, the composition can comprise a viscosity in a range from about 0.01 Pa-s to about 1,000 Pa-s, from about 0.01 Pa-s to about 500 Pa-s, from about 1 Pa-s to about 500 Pa-s, from about 1 Pa-s to about 100 Pa-s, from about 5 Pa-s to about 100 Pa-s, from about 5 Pa-s to about 50 Pa-s, from about 10 Pa-s to about 50 Pa-s, from about 10 Pa-s to about 30 Pa-s, or any range or subrange therebetween. In even further aspects, the composition can comprise a viscosity of about 0.01 Pa-s or more, about 0.1 Pa-s or more, about 0.5 Pa-s or more, about 30 Pa-s or less, about 10 Pa-s or less, about 6 Pa-s or less, or about 3 Pa-s or less. In even further aspects, the composition can comprise a viscosity in a range from about 0.01 Pa-s to about 30 Pa-s, from about 10 Pa-s, from about 0.01 Pa-s to about 6 Pa-s, from about 0.1 to about 6 Pa-s, from about 0.1 to about 3 Pa-s, from about 0.5 Pa-s to about 3 Pa-s, or any range or subrange therebetween.

The monomers in the thermoset polymer of the dielectric material can be bonded together by an alcohol or an ether. Without wishing to be bound by theory, cationic curing of epoxy-containing monomers produces ether and/or alcohol linkages. In aspects, the monomers in the thermoset polymer of the dielectric material can be bonded together by an alcohol, meaning that the carbon atom linking the reacted monomers together has a pendant —OH group. In aspects, the monomers in the thermoset polymer of the dielectric material can be bonded together by an ether group, meaning that the reacted monomers are bonded together by an oxygen atom.

As used herein, “surface roughness” means the Ra surface roughness, which is an arithmetical mean of the absolute deviations of a surface profile from an average position in a direction normal to the surface of the test area. As used herein, a “peak-to-valley” refers to the greatest vertical difference between any adjacent pair of a peak and a valley over the test area. Unless otherwise indicated, all Ra surface roughness values and peak-to-valley measurements are the measured average roughness (Ra) for an 80 μm by 80 μm test area using atomic force microscopy (AFM). The dielectric material can comprise an as-cured surface roughness Ra of about 5 nm or less, 2 nm or less, 1 nm or less, about 0.9 nm or less, about 0.1 nm or more, about 0.2 nm or more, about 0.5 nm or more, or about 0.7 nm or more, for example, from about 0.1 nm to about 5 nm, from about 0.2 nm to about 2 nm, from about 0.2 nm to about 1 nm, from about 0.5 nm to about 0.9 nm, from about 0.7 nm to about 0.8 nm, or any range or subrange therebetween.

As used herein, “dielectric constant” is measured in accordance with ASTM D2149-13(2021) using a precision capacitor. The dielectric constant refers to a ratio of an electric permeability of a material to the electric permeability of free space (i.e., vacuum). In aspects, a dielectric constant of the dielectric material at 1000 Hertz (Hz) can be about 15 or more, about 20 or more, about 25 or more, about 28 or more, about 35 or less, about 32 or less, or about 30 or less. In aspects, the dielectric constant of the dielectric material at 1000 Hz can range from about 15 to about 35, from about 20 to about 32, from about 25 to about 30, from about 28 to about 30, or any range or subrange therebetween. Providing a high dielectric (e.g., about 15 or more) can improve the performance of electronic devices (e.g., OTFTs, capacitors) that it is incorporated in.

Methods of forming the thermoset polymer of the dielectric material comprise reacting a first monomer (e.g., plurality of first monomers) and a second monomer (e.g., plurality of second monomers). With reference to FIGS. 3-4, the first monomer can comprise a dipolar functional group D1 and a first functional group (e.g., shown as an epoxy and/or glycidyl functional group) attached to the dipolar functional group D1 by box 305. Although the epoxy and/or glycidyl functional group is shown as being attached to box 305 at two points (e.g., carbon-carbon bonds), it is to be understood that the epoxy and/or glycidyl functional group could be terminal (i.e., attached to box 305 at only one point). Box 305 can comprise any organic functional group or combinations thereof. For example, as shown in FIG. 5, the first monomer 503 comprises the glycidyl and/or epoxy functional group attached to the dipolar functional group (e.g., methylsulfone) by a combination of a cycloalkyl ring (i.e., cyclohexane) and an alkyl carboxylic acid (e.g., ethanoate). The dipolar functional group D1 can be any of the groups discussed above for the dipolar functional group. With reference to FIG. 3, the second monomer is a functionalized oligomeric silsesquioxane containing box 303, and the functional groups R1-R3 can comprise any of the functional groups discussed above for functionalizing the functionalized oligomeric silsesquioxane. As shown in FIG. 4, the functionalized oligomeric silsesquioxane can be a functionalized POSS, and/or the functionalized oligomeric silsesquioxane can be functionalized by a glycidyl and/or epoxy functional group (e.g., alkyl epoxy, alkyl glycidyl, cycloalkyl epoxy, cycloalkyl glycidyl). As discussed above, a ratio of the second monomer to the first monomer, in wt %, can range from about 1 to about 3, from about 1.5 to about 2.8, from about 2 to about 2.5, or any range or subrange therebetween.

As shown in FIGS. 3-5, the first monomer and the second monomer are reacted under reaction conditions indicated by box 307. Box 307 (e.g., curing conditions) can comprise heating, irradiating, waiting a predetermined period of time, or a combination thereof. For example, box 307 can comprise heating the reactants (e.g., at a temperature from about 80° C. to about 150° C. for a period of time from about 1 minute to about 5 minutes) followed by irradiating the reactants (e.g., comprising a dose from about 100 milliJoules per centimeters squared (mJ/cm²) to about 1,600 mJ/cm²) including at least a photoinitiator. Precursor solutions comprising a higher amount of the second monomer may be cured with a lower radiation does than precursor solutions comprising lower amounts of the second monomer.

The product of the reactions shown in FIGS. 3-5 shows the first monomer bonded to the second monomer as a first step of polymerizing the thermoset polymer. As shown in FIG. 3, the reaction of functional group R1 becomes functional group R*, which can be an alcohol functional group or an ether functional group. As shown in FIGS. 4-5, the functional group R reacts to form an ether linkage between the reacted monomers. It is to be understood that a first step of the polymerization reaction could be between two first monomers or two second monomers. Likewise, it is to be understood that the polymerization reaction can involve the reaction of more than one first monomer and/or more than one second monomer to form the thermoset polymer. FIG. 6 shows a reaction of the first monomer containing the dipolar functional group RA and a functionalized POSS POSS-A to form different copolymers. For example, one or more reacted first monomers DB can be bonded together (e.g., a first monomers bonded together) with a terminal alcohol at one end and bonded to one or more reacted second monomers POSS-B (e.g., b second monomers bonded together) by an ether group, and one of the reacted second monomers can further be bonded to another reacted first monomer RB. In aspects, as shown in the top product, this can be a linear polymer. In aspects, as shown in the bottom product, this can be a branched polymer with the branching occurring at one or more reacted second monomers POSS-C. In further aspects, product can comprise one or more branching points, which can be adjacent to one another (e.g., c branching points at the reacted second polymer POSS-C) and/or spaced apart by additional reacted monomers (e.g., at least d separated branching points at the reacted second polymer POSS-C). It is to be understood that the branching points (e.g., POSS-C) can be directly bonded to 3, 4, 5, 6, 7, or 8 reacted monomers, and branching points in the same thermoset polymer can be directly bonded to the same number or a different number of reacted monomers. Also, it is to be understood that the thermoset polymer comprises a random copolymer even though a limited section of the copolymer is shown in FIG. 6.

Example ranges R1-R5 of compositions in aspects of the disclosure are presented in Table 1. Range R1 is the broadest of the ranges in Table 1. Ranges R3-R5 present subranges for the first monomer and the second monomer with range R3 corresponding to a higher amount of the first monomer, range R4 corresponding to a lower amount of the second monomer, and range R5 corresponding to an intermediate amount of the second monomer. It is to be understood that other ranges or subranges discussed above for these components can be used in combination with any of the ranges presented in Table 1. Example ranges R6-R9 of thermoset polymers of the dielectric material in aspects of the disclosure are presented in Table 2. Range R6 is the broadest of the ranges in Table 2. Ranges R7-R9 present subranges for the first monomer and the second monomer with range R7 corresponding to a higher amount of the first monomer, range R8 corresponding to a lower amount of the second monomer, and range R9 corresponding to an intermediate amount of the second monomer.

TABLE 1
Composition ranges (wt %) of aspects of compositions

| Range | R1 | R2 | R3 | R4 | R5 |
|---|---|---|---|---|---|
| First Monomer | 20-50 | 20-50 | 35-50 | 20-35 | 30-40 |
| Second Monomer | 45-75 | 45-75 | 45-60 | 65-75 | 55-65 |
| Photoinitiator | 0-5 | 1-5 | 2-4 | 2-4 | 2-4 |
| Photosensitizer | 0-5 | 1-3 | 1-3 | 1-3 | 1-3 |
| Catalyst | 0-3 | 0 | 0 | 0 | 0 |
| Solvent | 0.1-2 | 0.1-2 | 0.2-1 | 0.2-1 | 0.2-1 |

TABLE 2
Composition ranges (wt %) of aspects of thermoset polymers

| Range | R6 | R7 | R8 | R9 |
|---|---|---|---|---|
| First Monomer | 25-50 | 35-50 | 25-35 | 30-40 |
| Second Monomer | 50-75 | 50-65 | 65-75 | 60-70 |

FIGS. 1-2 schematically illustrate example aspects of an electronic device 102 containing the dielectric material 103 in a transistor 101 and in a capacitor 201, respectively. As shown, the dielectric material 103 comprises a first major surface 105 and a second major surface 107 opposite the first major surface 105. In aspects, as shown in FIG. 1, the second major surface can comprise portions 107a and 107b that lie in a common plane and other portions 107c that does not line in a common plane with portions 107a and 107b. As shown in FIGS. 1-2, a minimum thickness 109 or 209 of the dielectric material 103 is defined as a minimum distance between the first major surface 105 and the second major surface 107 in a direction perpendicular to the first major surface 105. In aspects, as shown in FIG. 2, the minimum thickness 209 can be substantially equal to an average thickness between the first major surface 105 and the second major surface 107, and/or a local thickness of the dielectric material 103 can be substantially constant across the first major surface 105. In aspects, the minimum thickness 109 or 209 can be about 100 nm or more, about 200 nm or more, about 500 nm or more, about 1 μm or more, about 5 μm or less, about 3 μm or less, or about 1 μm or less. In aspects, the minimum thickness 109 or 209 can range from about 100 nm to about 5 μm, from about 200 nm to about 3 μm, from about 500 nm to about 1 μm, or any range or subrange therebetween.

The transistor 101 can be a TFT and/or an OTFT. As shown in FIG. 1, the transistor 101 comprises a source electrode 133, a drain electrode 143, and a gate electrode 153. The source electrode 133 and the drain electrode 143 can be on the same side (e.g., first major surface 105) of the dielectric material 103, and the gate electrode 153 can be disposed on the second major surface 107 of the dielectric material 103 (e.g., a first contact surface 155 of the gate electrode 153 can contact portion 107c of the second major surface 107) opposite the source electrode 133 and the drain electrode 143. In aspects, the source electrode 133, the drain electrode 143, and/or the gate electrode 153 can comprise a metallic conductor (e.g., copper, aluminum, silver, gold) and/or a conductive polymer (e.g., Poly(p-phenylene vinylene) (PPV), poly(3,4-ethylenedioxythiophene) (PEDOT), a polyacetylene, a polypyrrole, a polyaniline, a polythiophene).

As shown in FIG. 1, the transistor 101 can further comprise a semiconductor 123 positioned between source electrode 133 and the gate electrode 153. The semiconductor material comprises a third major surface 125 and a fourth major surface 127 opposite the third major surface 125 with a semiconductor thickness 129 defined as an average distance therebetween. In aspects, the semiconductor thickness 129 can be within one or more of the ranges discussed above for the minimum thickness 109 or 209 of the dielectric material 103. In aspects, as shown, the fourth major surface 127 of the semiconductor 123 can be disposed on and/or contact the first major surface 105 of the dielectric material 103, and/or a third contact surface 137 of the source electrode 133 and/or a fourth contact surface 147 of the drain electrode 143 can be disposed on and/or contact the third major surface 125 of the semiconductor 123. However, it is to be understood that, in aspects, the position of the semiconductor and the dielectric material can be switched or that the semiconductor can be omitted.

As shown in FIG. 1, the second major surface of the dielectric material 103 and/or a second contact surface 157 of the gate electrode 153 can be disposed on and/or contact a fifth major surface 115 of a substrate 113. In aspects, the substrate 113 can comprise a polymeric material, a glass-based material, or a ceramic-based material. As used herein, “glass-based” includes both glasses and glass-ceramics, wherein glass-ceramics have one or more crystalline phases and an amorphous, residual glass phase. A glass-based material (e.g., glass-based substrate) may comprise an amorphous material (e.g., glass) and optionally one or more crystalline materials (e.g., ceramic). Exemplary glass-based materials, which may be an alkali-free glass and/or comprise a low content of alkali metals (e.g., R₂O of about 10 mol % or less, wherein R₂O comprises Li₂O Na₂O, and K₂O). As used herein, “ceramic-based” includes both ceramics and glass-ceramics, wherein glass-ceramics have one or more crystalline phases and an amorphous, residual glass phase. In aspects, ceramic-based materials can comprise one or more oxides, nitrides, oxynitrides, carbides, borides, and/or silicides. An exemplary aspects of a ceramic-based material include polycrystalline silicon wafers (e.g., n-doped) and monocrystalline silicon wafers (e.g., n-doped). Exemplary aspects of polymeric materials for the substrate 113 include homopolymers, copolymers, blends, and/or composites of a polyolefin, an epoxy resin, a polyurethane, a polyimide, a polyamide, and/or a polyacrylate. Although not shown, the substrate can comprise a recess that the drain electrode is positioned in such that the dielectric material comprises a substantially uniform thickness. Likewise, although not shown, the source electrode and the drain electrode can contact the fifth major surface of the substrate with the gate electrode positioned opposite relative to the dielectric material.

As shown in FIG. 2, the capacitor 201 can comprise the dielectric material 103 positioned between a first electrode 203 and a second electrode 213. In aspects, as shown, a first contact surface 205 of the first electrode 203 can contact the second major surface 107 of the dielectric material 103, and/or a second contact surface 217 of the second electrode 213 can contact the first major surface 105 of the dielectric material 103.

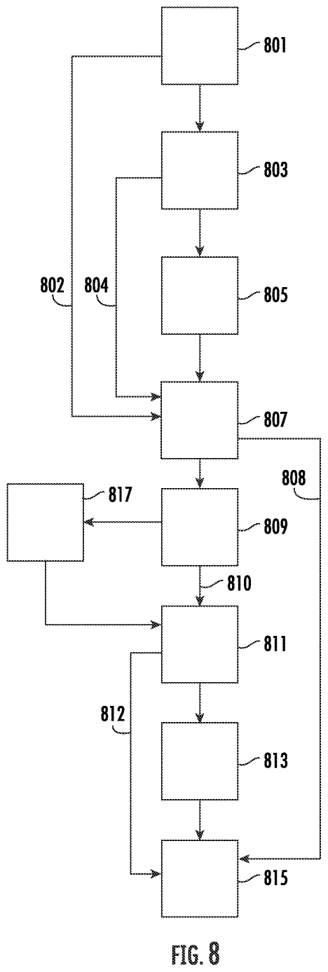

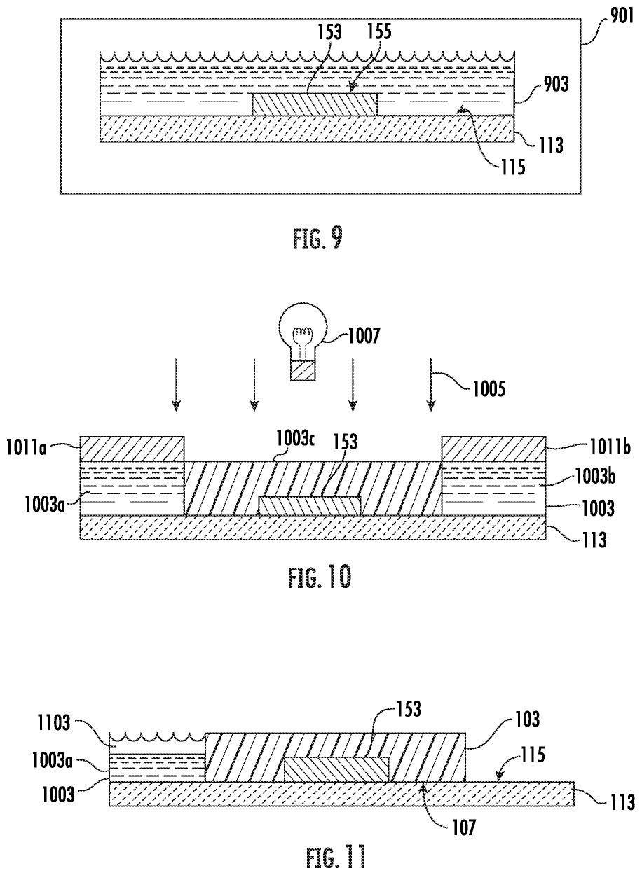

Aspects of methods of making the dielectric material 103 and/or the electronic device 102 comprising the dielectric material 103 in accordance with aspects of the disclosure will be discussed with reference to the flow chart in FIG. 8 and example method steps illustrated in FIGS. 9-11. With reference to the flow chart of FIG. 8, methods can start at step 801. In aspects, step 801 can comprise providing a precursor solution and either a substrate or an electrode. The substrate or the electrode can be provided by purchase or otherwise obtaining the substrate or the electrode. As discussed above, the substrate can be a glass-based substrate and/or a ceramic-based substrate, which can be formed, for example, with a ribbon forming process. As discussed above, the substrate or the electrode can comprise a polymeric material, which can be formed through, for example, extrusion, injection molding, additive manufacturing, or casting. The precursor solution comprises a first monomer and a second monomer. In aspects, the precursor solution further comprises a solvent and one or more of a catalyst, a photoinitiator, and a photosensitizer. The first monomer and the second monomer can comprise the one or more of the materials discussed above for the first monomer or the second monomer, respectively.

After step 801, as shown in FIG. 9, methods can proceed to step 803 of disposing a precursor solution 903 on the substrate 113 and/or an electrode 153 (e.g., on the fifth major surface 115 of the substrate, on the first contact surface 155 of the electrode 153). In aspects, disposing the precursor solution can comprise dispensing the precursor solution from a container (e.g., conduit, flexible tube, micropipette, or syringe). In aspects, disposing the precursor solution can comprise spin coating the precursor solution to form a substantially uniform free surface of the precursor solution. In aspects, disposing the precursor solution can comprise using a doctor blade and/or drawing an applicator bar across the precursor solution to form a substantially uniform free surface of the precursor solution. In aspects, disposing the precursor solution 903 can comprise using a roller (e.g., gravure or knife over roll coating).

After step 803, as shown in FIG. 9, methods can proceed to step 805 of heating the precursor solution 903 at a first temperature for a first period of time to form a precursor layer 1003 (see FIG. 10). The first temperature can be about 80° C. or more, about 100° C. or more, about 120° C. or more, about 150° C. or less, about 140° C. or less, or about 130° C. or less. For example, the first temperature can range from about 80° C. to about 150° C., from about 100° C. to about 140° C., from about 120° C. to about 130° C., or any range or subrange therebetween. In aspects, as shown in FIG. 9, heating the precursor solution 903 can comprise placing the precursor solution 903 in an oven 901 maintained at the first temperature. Step 805 can remove at least a portion of the solvent, if present, and/or increase a viscosity of the precursor solution 903. In aspects, step 805 can start a cationic polymerization reaction.

After step 805, as shown in FIG. 10, methods can proceed to step 807 of disposing a photomask 1011a and/or 1011b on a portion (e.g., covered portion 1003a and/or 1003b) of the precursor layer 1003. The portion(s) of the precursor layer 1003 that the photomask 1011a and/or 1011b is disposed on is referred to as a “covered portion” while the remaining portions are referred to as “exposed portions.” The photomask 1011a and/or 1011b can correspond to regions where the resulting dielectric material will not be in the resulting electronic device. The photomask 1011a and/or 1011b comprises a material that is optically opaque at a wavelength of light used in step 809.

After step 807, as shown in FIG. 11, methods can proceed to step 809 of irradiating an exposed portion 1003c of the precursor layer 1003 to form the dielectric material 103 (see FIG. 12). As shown in FIG. 11, irradiating the exposed portion 1003c comprises impinging the exposed portion 1003c with radiation 1005 emitted from a radiation source 1007. The radiation source can comprise a light-emitting diode (LED), an organic light-emitting diode (OLED), a laser, an incandescent bulb, and/or a fluorescent bulb (e.g., a cold cathode fluorescent lamp (CCFL)). The radiation 1005 can comprise a wavelength that the photoinitiator is sensitive to. In further aspects, the radiation 1005 can comprise ultraviolet radiation and/or visible radiation. For example, the radiation 1005 can comprise ultraviolet radiation with an optical wavelength from about 100 nm to about 400 nm, from about 200 nm to about 350 nm, from about 250 nm to about 300 nm, or any range or subrange therebetween. In further aspects, the radiation 1005 can comprise an optical wavelength of about 365 nm, about 415 nm, or about 590 nm. In aspects, a dose of radiation delivered to the exposed portion can be about 100 milliJoules per centimeters squared (mJ/cm²) or more, about 400 mJ/cm² or more, about 600 mJ/cm² or more, about 1,600 mJ/cm² or less, about 1,200 mJ/cm² or less, about 1,000 or less, or about 600 mJ/cm² or less. In aspects, a dose of radiation delivered to the exposed portion can range from about 100 mJ/cm² to about 1,600 mJ/cm², from about 400 mJ/cm² to about 1,200 mJ/cm², from about 600 mJ/cm² to about 1,000 mJ/cm², or any range or subrange therebetween. Providing a dose corresponding to an energy density from about 100 mJ/cm² to about 1,600 mJ/cm² can produce a well-defined portion of the dielectric material corresponding to the exposed portion 1003c.

Alternatively, instead of steps 805, 807, and/or 809, methods can proceed to irradiating (e.g., with radiation 1005 emitted from a radiation source 1007 shown in FIG. 10) a portion (e.g., corresponding to cover portion 1003a in FIG. 10) of the precursor layer 1003.

In aspects, the irradiating can comprise direct laser writing or other methods that selectively irradiate the portion of the precursor layer 1003 (e.g., without the use of the photomask 1011a and/or 1011b). After the irradiating, the methods can proceed to step 817 or step 811, as discussed below.

In aspects, after step 809, methods can proceed to step 817 comprising heating the dielectric material 103 at a second temperature for a second period of time. Similar to step 805, as discussed above with reference to FIG. 9, the heating can comprise placing the material in an oven maintained at the corresponding temperature. The second temperature can be about 90° C. or more, about 100° C. or more, about 110° C. or more, about 150° C. or less, about 135° C. or less, or about 120° C. or less. For example, the second temperature can range from about 90° C. to about 150° C., from about 100° C. to about 135° C., from about 110° C. to about 120° C., or any range or subrange therebetween. The second period of time can be about 2 minutes or more, about 5 minutes or more, about 8 minutes or more, about 20 minutes or less, about 15 minutes or less, or about 10 minutes or less. For example, the second period of time can range from about 2 minutes to about 20 minutes, from about 5 minutes to about 15 minutes, from about 8 minutes to about 10 minutes, or any range or subrange therebetween. Without wishing to be bound by theory, heating the dielectric material in step 817 can accelerate a cross-linking and/or branching reaction with reacted second monomers. Heating the dielectric material after irradiating the precursor layer can increase a spatial resolution of the patterned dielectric material.

After step 809 or step 817, as shown in FIG. 12, methods can proceed to step 811 comprise contacting the covered portion 1003a with a developing solution 1103 to remove the covered portion 1003a of the precursor layer 1003. In aspects, step 811 further comprises removing the photomask 1011a and/or 1011b (if present) before removing the covered portion 1003a and/or 1003b. In aspects, the developing solution 1103 can be dispensed from a container (e.g., conduit, flexible tube, micropipette, or syringe). In aspects, the developing solution 1103 can comprise a solvent that removes the covered portion 1003a (e.g., by dissolving the covered portion 1003a). An exemplary aspect of the developing solution 1103 is propylene glycol methyl ether acetate (PGMEA, available as Dowanol PMA from Dow Chemical). In further aspects, the covered portion 1003a can be contacted with the developing solution 1103 for about 1 second or more, about 5 seconds or more, about 10 seconds or more, about 10 minutes or less, about 2 minutes or less, or about 30 seconds or less to remove substantially all of the material of the covered portion 1003a. For example, the covered portion 1003a can be contacted with the developing solution 1103 for from about 1 second to about 10 minutes, from about 5 seconds to about 2 minutes, from about 10 seconds to about 30 seconds. Being able to remove covered portions (e.g., undeveloped material) with a solvent in a short period of time can increase processing efficiency and/or reduce processing costs.

After step 811, methods can proceed to step 813 comprising assembling an electronic device. For example, step 813 can include disposing a packaging (e.g., encapsulant, hermetic seal) and/or connecting the electrodes as part of a larger electronic device. The electronic device can be part of an article with a display (or display articles) (e.g., consumer electronics, including mobile phones, tablets, computers, navigation systems, wearable devices (e.g., watches) and the like), architectural articles, transportation articles (e.g., automotive, trains, aircraft, sea craft, etc.), appliance articles, etc.

After step 811 or 813, methods can be complete at step 815, whereupon methods of making the dielectric material 103 and/or the electronic device 102 comprising the dielectric material 103 can be complete. In aspects, the dielectric material can comprise a dielectric constant within one or more of the ranges discussed above for the dielectric constant. In aspects, as discussed above with reference to the flow chart in FIG. 8, methods can proceed sequentially through steps 801, 801, 805, 807, 809, 817, 811, 813, and 815. In aspects, arrow 802 can be followed from step 801 to step 807, for example, the precursor solution is to be cured to form the dielectric material independent from part of an electronic device. In aspects, arrow 804 can be followed from step 803 to step 807, for example, if the precursor solution is to be cured by irradiating the precursor solution and/or a photomask can be disposed on the precursor solution without partially curing the precursor solution. In aspects, arrow 808 can be followed from step 807 to step 815, for example, if the dielectric material is complete at the end of step 807. In aspects, arrow 810 can be followed from step 809 to step 811, for example, if the heating second temperature for a second period of time is to be omitted before removing the covered portion. In aspects, arrow 812 can be followed from step 811 to 815, for example, if the electronic device is complete at the end of step 811. Alternatively, instead of steps 805, 807, and/or 807, methods can proceed to irradiating a portion of the precursor layer 1003 using direct laser writing or other methods that selectively irradiate the portion of the precursor layer 1003 (e.g., without the use of the photomask 1011a and/or 1011b). Any of the above options may be combined to make a dielectric material and/or an electronic device in accordance with aspects of the disclosure.

### EXAMPLES

Various aspects will be further clarified by the following examples. Table 3 presents information about aspects of compositions, which were used to form the dielectric material in Examples A-F with properties reported in Table 4. Unless otherwise specified, the substrate used in Examples A-F and Table 3 is an n-doped silicon wafer. As used in Table 3, GCHEMS refers to the first monomer 503 shown in FIGS. 5 and 7 that is referred to as 3,4-gylcidylcycholhexylethoanatemethanesulfone (GCHEMS). EP0408 refers to a second monomer comprising (3,4-epoxycyclohexyl)ethyl functionalized POSS (available as EP0408 from Hybrid Plastics). PAG290 refers to a photoinitiator comprising example tris(4-((4-acetylphenyl)thio)phenyl)-sulfonium tetrakis(perfluorophenyl) (available as Irgacure PAG290 from BASF). ITS refers to a photoinitiator comprising 2-isopropylthioxanthen-9-one (available as Speedcure 2-ITX from Sartomer). Butyl acetate is a solvent in a concentration of about 300 milligrams of the composition (excluding the solvent) to 1 milliliter of the solvent (mg/mL).

TABLE 3
Composition ranges (wt %) of reactants

| Example | A-C | D-F |
|---|---|---|
| GCHEMS | 31.4 | 46.9 |
| EP0408 | 62.5 | 46.9 |
| PAG290 | 2.9 | 2.9 |
| ITX | 2.9 | 2.9 |
| Butyl Acetate | 0.3 | 0.3 |

As shown in Table 3, the composition for Examples A-C comprised a ratio of the second monomer (EP0408) to the first monomer (GCHEMS) of 3 while the composition for Examples D-F comprised a corresponding ratio of 1. The compositions for all of Examples A-F comprised equal amounts of photoinitiator (PAG290) and photosensitizer at 2.9 wt % each.

The precursor solutions for Examples A-F were disposed on the substrate by spin coating at 3,000 revolutions per minute (rpm) for 30 seconds. The disposed precursor solutions were heated at 110° C. for 2 minutes to form a precursor layer before four cut-out squares of 500 μm by 500 μm were irradiated spaced apart by 130 μm were irradiated by laser direct writing using a MicroWriter ML3 (Durham Magneto Optics Ltd.). Then, the precursor layer was irradiated with light comprising an optical wavelength of 385 nm for the dose stated in Table 4 and then heated at the temperature stated in Table 4 for 2 minutes. Afterwards, the pattern was developed by rinsing with propylene glycol methyl ether acetate (PGMEA) developing solution for 10 seconds.

TABLE 4
Curing Conditions and Properties of Examples A-F

| | Radiation | | |
|---|---|---|---|
| | Dose | Additional | |
| Example | (mJ/cm²) | Heating (° C.) | Evaluation |
| A | 200 | n/a | Uneven |
| B | 200 | 110° C. | Good |
| C | 200 | 130° C. | Residues around exposed portion |
| D | 800 | n/a | Uneven, scattered residue |
| E | 800 | 90° C. | Good |
| F | 800 | 110° C. | Residues around exposed portion |

As shown in Table 4, Examples A-C were treated with a radiation dose of 200 mJ/cm² while Examples D-F were treated with a radiation dose of 800 mJ/cm². The radiation dose was related to the content of the second monomer since more second monomer increased the degree of cross-linking and/or branching of the resulting thermoset polymer. Examples A and C were not additionally heated after the radiation dose. Examples A and C had uneven thickness in the exposed portions, and Example C had deposited material (i.e., residue) that was not removed with the developing solution. For both Examples A and C, it is believed that the material was not sufficiently cross-linked and/or branched to form stable layers or uniform thickness in the exposed portions. For Example C, it is believed that the residues were formed from cured segments from the exposed portion adhering to the substrate when adjacent, uncured segments were washed away by the developing solution.

Example C comprised additional heating at 130° C. for 2 minutes after treatment with the radiation dose, and Example F comprised additional heating at 110° C. for 2 minutes after treatment with the radiation dose. Examples C and F had an average thickness for the exposed portions of about 300 nm, but they also had residues around the exposed portion (including between adjacent exposed portions) that were not removed by the developing solution. It is believed that the heat treatment in Examples C and F lead to cross-linking and/or branching of the material in the exposed portions extending beyond the exposed portions, which led to the formation of the residues.

Example B comprised additional heating at 110° C. for 2 minutes after treatment with the radiation dose, and Example E comprised additional heating at 90° C. for two minutes after treatment with the radiation dose. Examples B and E comprised an average thickness for the exposed portions of about 300 nm. Examples B and E comprised a surface roughness Ra for the exposed portions of about 0.89 nm. Examples B and E had good resolution of the patterned dielectric corresponding to the exposed portions without any noticeable residue. The dielectric constant was measured for Example B at frequencies from 100 Hz to 1,000 Hz. At 100 Hz, the dielectric constant was about 31, and the dielectric constant smoothly decreased to about 30 at 1,000 Hz.

The above observations can be combined to provide compositions for forming a polymer, dielectric materials comprising a polymer, and electronic devices containing the dielectric materials comprising a polymer. The dielectric material comprises a thermoset polymer, which reduces concerns about dimensional stability at elevated temperatures relative to a thermoplastic polymer. The dielectric material provides an organic polymer comprising a high dielectric constant (e.g., about 15 or more) that can improve the performance of electronic devices (e.g., OTFTs, capacitors) that it is incorporated in. The dielectric material and/or the first monomer comprises a dipolar functional group can reduce a decrease in dielectric constant as frequency increases to provide a more uniform dielectric constant across frequencies and a relatively higher dielectric constant at higher frequencies than might otherwise be expected. The dielectric material can comprise a low surface roughness Ra (e.g., about 5 nanometers or less or about 1 nanometer or less).

The dielectric material can be formed as a random copolymer of a first monomer and a second monomer. Providing a functionalized oligomeric silsesquioxane can increase a degree of branching and/or cross-linking of the resulting dielectric material, which can increase an effectiveness of photopatterning the dielectric material and/or reduce processing time. Providing more of the second monomer than the first monomer can produce well-defined, photo-patterned structures, for example, because the functionalized oligomeric silsesquioxanes can increase a cross-linking density of the resulting dielectric material. Providing a ratio of the second monomer to the first monomer of about 3 or less can enable a high dielectric constant. Providing a first monomer containing a glycidyl functional group and/or an epoxy functional group as well as a second monomer containing a glycidyl functional group and/or an epoxy functional group can simplify the curing reaction while allowing for a random copolymer to form, become cross-linked, and/or become branched. The dielectric material can be photopatterned and developed with a common solvent, reducing processing complexity and cost.

Providing a cationic photoinitiator allows the epoxy and/or glycidyl containing monomers to cure to produce a photo-patternable dielectric material. Providing a photosensitizer can increase a state of cure and/or a curing rate for the composition, which can minimize processing time and/or improve the resolution of a resulting photo-patterned dielectric material. Heating the precursor solution (e.g., composition) before irradiating the precursor solution can remove solvent, which can increase a subsequent polymerization reaction rate to reduce an overall processing time. Heating the dielectric material after irradiating the precursor layer can increase a spatial resolution of the patterned dielectric material. Providing a composition substantially free and/or free of nanoparticles (e.g., silica nanoparticles) can reduce processing issues (e.g., agglomeration, aggregation, phase separation) with the composition, improve optical properties (e.g., maintain low haze and/or high transmittance even after aging at elevated temperature and/or humidity) of the coating and/or the resulting coating and/or coated article, and reduce mechanical properties (e.g., hardness, modulus, strain) of the resulting dielectric material compared to a corresponding composition and/or dielectric material comprising a plurality of functionalized oligomeric silsesquioxanes without silica nanoparticles.

Directional terms as used herein—for example, up, down, right, left, front, back, top, bottom—are made only with reference to the figures as drawn and are not intended to imply absolute orientation.

It will be appreciated that the various disclosed aspects may involve features, elements, or steps that are described in connection with that aspect. It will also be appreciated that a feature, element, or step, although described in relation to one aspect, may be interchanged or combined with alternate aspects in various non-illustrated combinations or permutations.

It is also to be understood that, as used herein the terms “the,” “a,” or “an,” mean “at least one,” and should not be limited to “only one” unless explicitly indicated to the contrary. For example, reference to “a component” comprises aspects having two or more such components unless the context clearly indicates otherwise. Likewise, a “plurality” is intended to denote “more than one.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art. Ranges can be expressed herein as from “about” one particular value, and/or to “about” another particular value. When such a range is expressed, aspects include from the one particular value and/or to the other particular value. Similarly, when values are expressed as approximations, by use of the antecedent “about,” it will be understood that the particular value forms another aspect. Whether or not a numerical value or endpoint of a range in the specification recites “about,” the numerical value or endpoint of a range is intended to include two aspects: one modified by “about,” and one not modified by “about.” It will be further understood that the endpoints of each of the ranges are significant both in relation to the other endpoint and independently of the other endpoint.

The terms “substantial,” “substantially,” and variations thereof as used herein are intended to note that a described feature is equal or approximately equal to a value or description. For example, a “substantially planar” surface is intended to denote a surface that is planar or approximately planar. Moreover, as defined above, “substantially similar” is intended to denote that two values are equal or approximately equal. In aspects, “substantially similar” may denote values within about 10% of each other, for example, within about 5% of each other, or within about 2% of each other.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

While various features, elements, or steps of particular aspects may be disclosed using the transitional phrase “comprising,” it is to be understood that alternative aspects, including those that may be described using the transitional phrases “consisting” or “consisting essentially of,” are implied. Thus, for example, implied alternative aspects to an apparatus that comprises A+B+C include aspects where an apparatus consists of A+B+C and aspects where an apparatus consists essentially of A+B+C. As used herein, the terms “comprising” and “including”, and variations thereof shall be construed as synonymous and open-ended unless otherwise indicated.

The above aspects, and the features of those aspects, are exemplary and can be provided alone or in any combination with any one or more features of other aspects provided herein without departing from the scope of the disclosure.

It will be apparent to those skilled in the art that various modifications and variations can be made to the present disclosure without departing from the spirit and scope of the disclosure. Thus, it is intended that the present disclosure cover the modifications and variations of the aspects herein provided they come within the scope of the appended claims and their equivalents.

What is claimed is:

1. A dielectric material comprising:
a thermoset polymer comprising a random copolymer of:
a first monomer comprising a dipolar functional group and a first functional group, the dipolar functional group comprising a dipole moment of 3.9 Debye or more; and
a second monomer comprising a functionalized oligomeric silsesquioxane,
wherein the thermoset polymer comprises a dielectric constant ranging from 15 to 35 at 1000 Hertz.

2. The dielectric material of claim 1, wherein the dipolar functional group is selected from a group consisting of sulfones, sulfates, cyanides, and thiiranes.

3-4. (canceled)

5. The dielectric material of claim 1, wherein the first monomer and the second monomer are bonded together by an alcohol or an ether.

6. The dielectric material of claim 1, wherein the functionalized oligomeric silsesquioxane is a functionalized polyhedral oligomeric silsesquioxane.

7. The dielectric material of claim 1, wherein a ratio in wt % of the second monomer to the first monomer ranges from 1 to 3.

8. The dielectric material of claim 1, wherein a major surface of the dielectric material comprising a surface roughness Ra of 5 nanometers or less.

9. The dielectric material of claim 1, further comprising a photoinitiator comprising from 1 wt % to 5 wt % of the dielectric material.

10. (canceled)

11. A method of forming a dielectric material comprising:
disposing a precursor solution on a substrate;
heating the precursor solution at a first temperature from 80° C. to 150° C. for a first period of time from 1 minute to 5 minutes to form a precursor layer;
irradiating a portion of the precursor layer to form the dielectric material;
contacting the covered portion with a developing solution to remove the covered portion of the precursor layer,
wherein the dielectric material is a thermoset polymer.

12. The method of claim 11, further comprising, before contacting the covered portion with the developing solution, heating the dielectric material at a second temperature from 90° C. to 150° C. for a second period of time from 2 minutes to 20 minutes.

13. The method of claim 11, wherein irradiating the exposed portion comprising delivering a dose from 100 milliJoules per centimeters squared (mJ/cm²) to 1,600 mJ/cm².

14. The method of claim 11, further comprising, before the irradiating, disposing a photomask on a covered portion of the precursor layer.

15. The method of claim 11, wherein the precursor solution comprises:
a solvent;
a first monomer comprising a first functional group and either a dipolar functional group comprising a dipole moment of 3.9 Debye or more or a sulfur atom;
a second monomer comprising a functionalized oligomeric silsesquioxane; and
a photoinitiator.

16. The method of claim 15, wherein the first monomer comprises the dipolar functional group, the dipolar functional group is selected from a group consisting of sulfones, sulfates, cyanides, and thiiranes.

17. The method of claim 15, wherein the first functional group is an epoxy functional group or a glycidyl functional group.

18. The method of claim 15, wherein the functionalized oligomeric silsesquioxane is functionalized by a glycidyl functional group or an epoxy functional group.

19. The method of claim 15, wherein the functionalized oligomeric silsesquioxane is a functionalized polyhedral oligomeric silsesquioxane.

20. The method of claim 15, wherein a ratio in wt % of the second monomer to the first monomer ranges from 1 to 3.

21. The method of claim 11, wherein the thermoset polymer comprising a dielectric constant ranging from 15 to 35 at 1000 Hertz.

22. A dielectric material comprising:
a thermoset polymer comprising a copolymer of:
a first monomer comprising a sulfur atom and a first functional group, the first functional group comprising a glycidyl functional group or an epoxy functional group; and
a second monomer comprising a functionalized oligomeric silsesquioxane functionalized by a glycidyl functional group or an epoxy functional group.

23. The dielectric material of claim 22, wherein the thermoset polymer comprises a dielectric constant ranging from 15 to 35 at 1000 Hertz.
